(19) United States
(12) Patent Application Publication
(10) Pub. No.: US 2011/0095382 A1
(43) Pub. Date: Apr. 28, 2011

(54) MEMS DEVICE

(75) Inventor: Yoshiaki Shimooka, Tokyo (JP)

(73) Assignee: KABUSHIKI KAISHA TOSHIBA, Tokyo (JP)

(21) Appl. No.: 12/907,110

(22) Filed: Oct. 19, 2010

(30) Foreign Application Priority Data
Oct. 19, 2009 (JP) P2009-240641

(51) Int. Cl. H01L 29/84; H01L 21/02

(52) U.S. Cl. 257/415; 438/50; 257/E21.002; 257/E29.324

(57) ABSTRACT

A MEMS device of an embodiment includes: a MEMS element; a first cavity region provided on the MEMS element; a second cavity region provided on a surrounding portion outside the MEMS element, the second cavity region having a lower height than the first cavity region; a third cavity region provided on a surrounding portion outside the second cavity region, the third cavity region having a lower height than the second cavity region; an insulating film provided to cover upper portions and side surfaces of the first to the third cavity regions; an opening provided in the insulating film on the first to the third cavity regions; and a sealant provided on the insulating film to seal the opening and to retain the first to the third cavity regions.

### CROSS REFERENCE TO RELATED APPLICATION

This application is based upon and claims the benefit of priority from Japanese Patent Application No. 2009-240641, filed on Oct. 19, 2009, the entire contents of which are incorporated herein by reference.

### BACKGROUND

MEMS (Micro Electro Mechanical Systems) are devices having mechanical actuation portions, unlike normal semiconductor elements, ICs, LSIs, and the like. For mounting a MEMS device, a cavity region to hold the mechanical actuation portion needs to be provided in a mounting portion or in a package. As a method for forming a cavity region, there is a method in which a second sacrificial layer having a small area is provided on a first sacrificial layer, and then the first and the second sacrificial layers are removed to form a cavity region (U.S. Pat. No. 7,008,812)

A MEMS device described in U.S. Pat. No. 7,008,812 has a problem that a desired cavity structure is not formed because the first sacrificial layer at the bottom is etched during the pattern formation of the second sacrificial layer. Moreover, another problem occurs that the surface of the first sacrificial layer is roughened due to the process damage in the step of forming an insulating film on the cavity region, thereby causing a MEMS element and the second sacrificial layer to be peeled from the substrate in the subsequent step.

### BRIEF DESCRIPTIONS OF THE DRAWINGS

A more complete appreciation of the invention and many of the attendant advantages thereof will be readily obtained as the same becomes better understood by reference to the following detailed description when considered in connection with the accompanying drawings.

FIG. 1 is a schematic plan view showing a MEMS device according to Embodiment 1 of the present invention.

FIG. 2 is a cross-sectional view of the MEMS device taken along the line A-A in FIG. 1.

FIG. 3 is a cross-sectional view of the MEMS device taken along the line B-B in FIG. 1.

FIGS. 4 to 7 and 9 to 12 are cross-sectional views illustrating manufacturing steps for the MEMS device according to Embodiment 1 of the present invention.

FIG. 8 is a cross-sectional view illustrating a manufacturing step for a MEMS device of Comparative Example according to Embodiment 1 of the present invention.

FIG. 13 is a cross-sectional view showing a MEMS device according to Embodiment 2 of the present invention.

FIGS. 14 and 15 are cross-sectional views illustrating manufacturing steps for the MEMS device according to Embodiment 2 of the present invention.

FIG. 16 is a cross-sectional view illustrating a manufacturing step for a MEMS device according to Embodiment 3 of the present invention.

FIG. 17 is a cross-sectional view of a MEMS device of a modified example taken along the line B-B in FIG. 1.

### DETAILED DESCRIPTION

Various connections between elements are hereinafter described. It is noted that these connections are illustrated in general and, unless specified otherwise, may be direct or indirect and that this specification is not intended to be limiting in this respect.

Embodiments of the present invention will be explained with reference to the drawings as next described, wherein like reference numerals designate identical or corresponding parts throughout the several views.

### First Embodiment

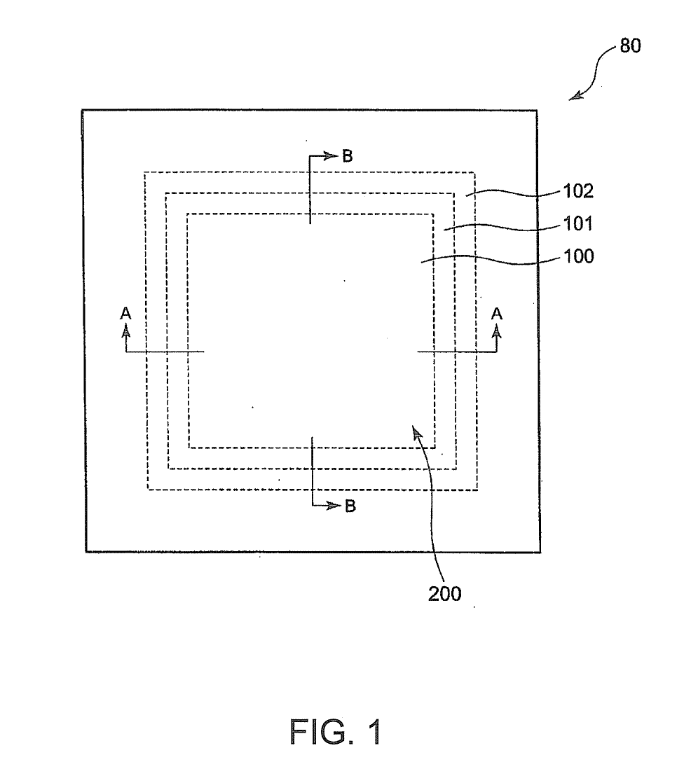

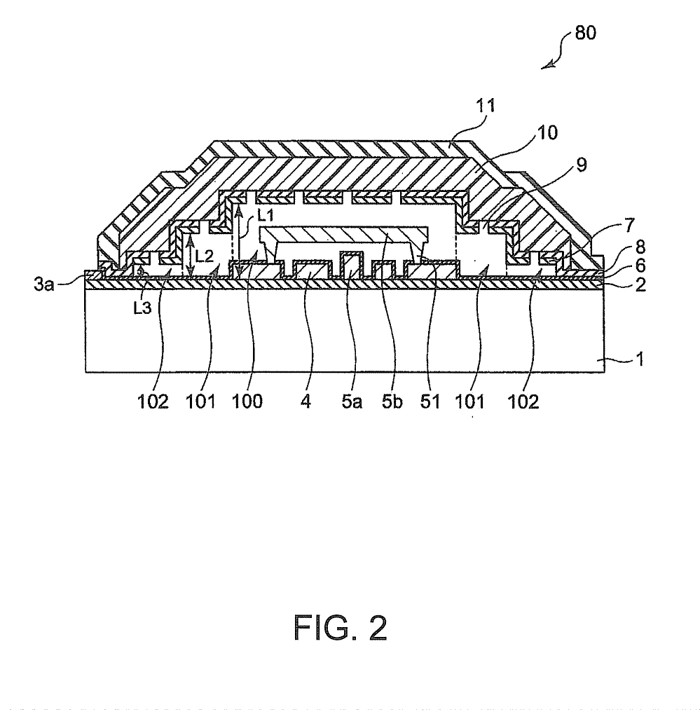

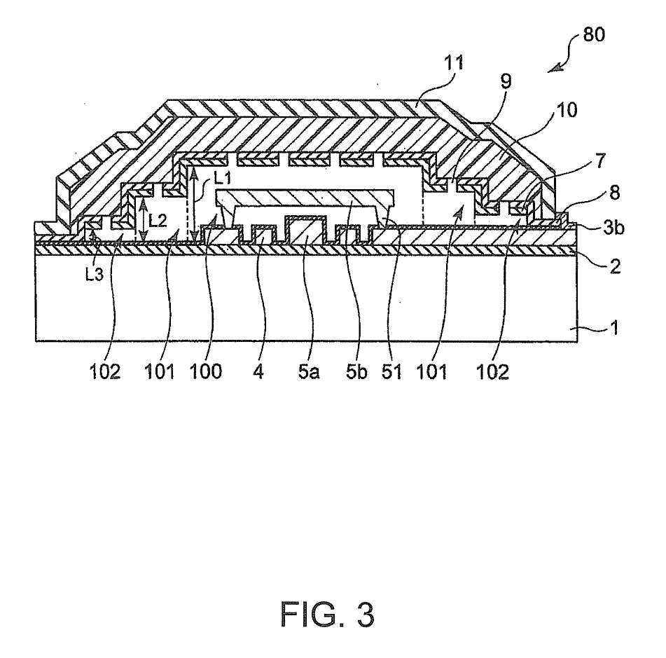

First, a MEMS device and a method for manufacturing a MEMS device according to Embodiment 1 of the present invention will be described with reference to the drawings. FIG. 1 is a schematic plan view showing the MEMS device. FIG. 2 is a cross-sectional view of the MEMS device taken along the line A-A in FIG. 1. FIG. 3 is a cross-sectional view of the MEMS device taken along the line B-B in FIG. 1. In this embodiment, three cavity regions having different heights are provided on and around an MEMS element region.

As shown in FIG. 1, a MEMS element region 200 is provided in a central portion of a MEMS device 80. The MEMS element region 200 is hermetically sealed with an unillustrated sealant. A first cavity region 100 is provided on the MEMS element region 200. A second cavity region 101 is provided on a surrounding portion outside the first cavity region 100. A third cavity region 102 is provided on a surrounding portion outside the second cavity region 101. Incidentally, the cavity regions may also be called a cavity. The MEMS device 80 is an RF-MEMS provided with an actuation portion in the MEMS element region 200. The RF-MEMS is employed to, for example, high-frequency components for mobile devices and the like, and specifically employed to a device such as a switch, a filter, or a varactor.

As shown in FIG. 2, in the MEMS device 80, an interlayer insulating film 2 is provided on a substrate 1 constituted of a silicon substrate, for example. A terminal 3a and a wiring layer 4 are provided on the interlayer insulating film 2. A portion of the wiring layer 4 is used as a first electrode 5a serving as the actuation portion of the MEMS element, whereas the other portion is used as an interconnection wiring in the MEMS element or as a connection wiring to the outside of the MEMS element. Note that an unillustrated IC or LSI is provided in advance at an upper portion of the substrate 1 constituted of the silicon substrate. The terminal 3a is a chip terminal for the IC or LSI.

An insulating film 6 serving as a protection film is provided on the interlayer insulating film 2, the wiring layer 4, and the first electrode 5a. The insulating film 6 is also provided on an upper end portion of the terminal 3a. Openings are provided in the insulating film 6 on the wiring layer 4. A wiring layer is provided in each of the openings. Specifically, a second electrode 5b having anchor portions 51 that are in contact with the wiring layer 4 is provided in the openings, the second electrode 5b being above and apart from the first electrode 5a. The first electrode 5a and the second electrode 5b serve as the actuation portion of the MEMS element.

The first cavity region 100 having a distance L1 between the substrate and an insulating film is provided in the MEMS element region 200. The second cavity region 101 having a distance L2 between the substrate and the insulating film is provided on the insulating film 6 on the surrounding portion outside the first cavity region 100. The third cavity region 102 having a distance L3 between the substrate and the insulating film is provided on the insulating film 6 on the surrounding portion outside the second cavity region 101. The first cavity region 100, the second cavity region 101, and the third cavity region 102 are filled with air, for example. Incidentally, an inert gas (for example, a nitrogen gas) may be filled in place of air.

Here, the relationship among the distance L1 between the substrate and the insulating film, the distance L2 between the substrate and the insulating film, and the distance L3 between the substrate and the insulating film is set as:

L1>L2>L3 Formula (1).

An insulating film 7 is provided on the first cavity region 100, the second cavity region 101, and the third cavity region 102. An insulating film 8 is provided on the insulating film 7 and a side surface of the third cavity region 102. In other words, the insulating films 7 and 8 define the first cavity region 100, the second cavity region 101, and the third cavity region 102. The insulating films 7 and 8 are provided to cover the MEMS element region 200. Openings 9 are provided in the laminated insulating films 7 and 8 on the first cavity region 100, the second cavity region 101, and the third cavity region 102. An organic film 10 is provided on the insulating film 8 to seal the openings 9. An insulating film 11 is provided on the organic film 10 and the insulating film 8.

Here, the organic film 10 and the insulating film 11 function as a sealant for sealing the MEMS element. Aluminum (Al) is used as the terminal 3a, the wiring layer 4, the first electrode 5a, and the second electrode 5b; instead, a metal such as copper (Cu) may be used. A silicon nitride film (SiN film) is used as the insulating film 6, the insulating film 7, the insulating film 8, and the insulating film 11; instead, a silicon oxide film (SiO₂), a SiON film, a SiOCH film, or the like may be used. A polyimide resin is used as the organic film 11; instead, an organic film such as a BCB (Benzo-Cycro-Buten) resin, a fluorinated resin (parylen-N or the like), or a polyamide resin may be used.

As shown in FIG. 3, the wiring layer 4 provided on the MEMS element region extends outwards of a region where the organic film 10 and the insulating film 11 serving as the sealant are provided. The wiring layer 4 is connected to a terminal 3b provided on an upper portion thereof. When a module for the MEMS device 80 is formed, for example, a bump is formed on an upper portion of the terminal 3b to perform bonding through the bump.

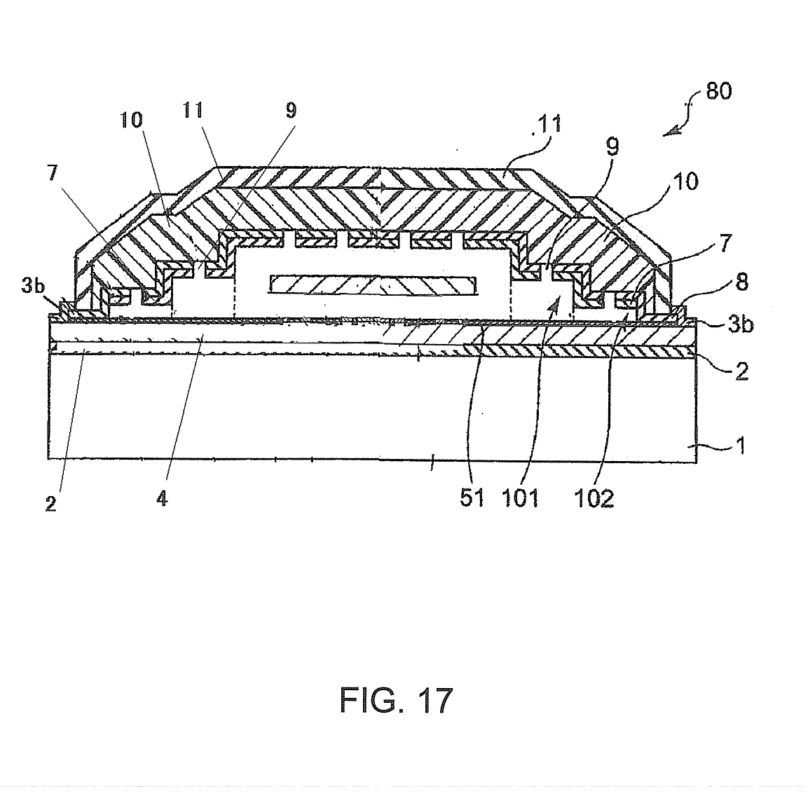

Note that, as shown in FIG. 17, a structure may be constructed in which the MEMS device 80 has a structure as illustrated on a right side of the MEMS device 80 of FIG. 3 and is symmetrical with respect to a line which passes through the center of the MEMS element and which is perpendicular to the substrate 1.

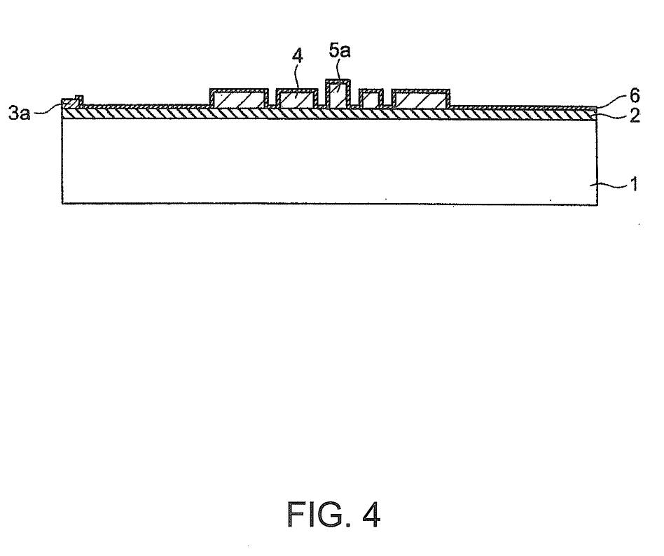

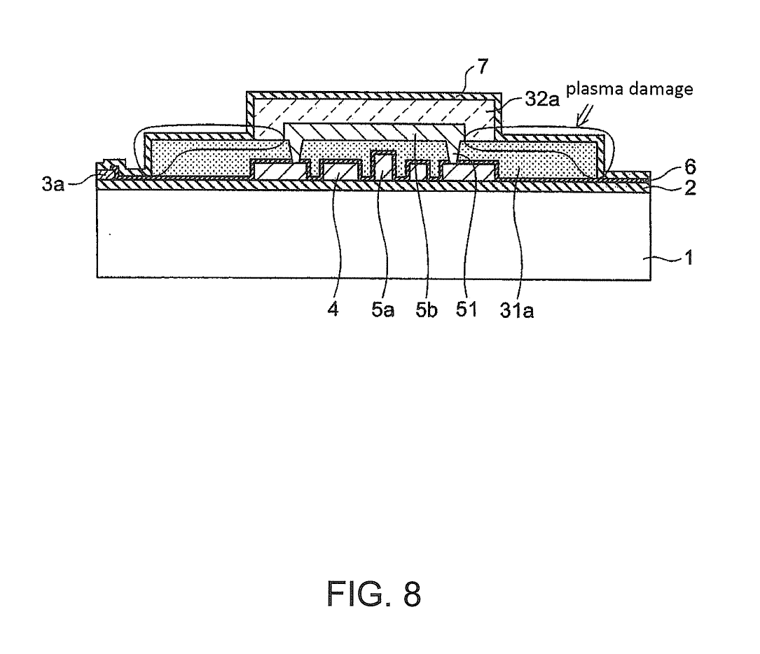

Next, a method for manufacturing a MEMS device will be described with reference to FIGS. 4 to 12. FIGS. 4 to 7 and FIGS. 9 to 12 are cross-sectional views illustrating manufacturing steps for the MEMS device. FIG. 8 is a cross-sectional view illustrating a manufacturing step for a MEMS device of Comparative Example.

As shown in FIG. 4, the wiring layer 4 and the first electrode 5a are formed to have thicknesses in the range of several hundred nm to several um on the interlayer insulating film 2. The insulating film 6 serving as the protection film for the wiring layer 4 and the first electrode 5a is formed by using a CVD (Chemical Vapor Deposition) process, for example, to have a thickness in the range of several hundred nm to several um on the interlayer insulating film 2, the wiring layer 4 and the first electrode 5a. After the insulating film 6 is formed, the insulating film 6 on the terminal 3a is etched away except for an end portion thereof.

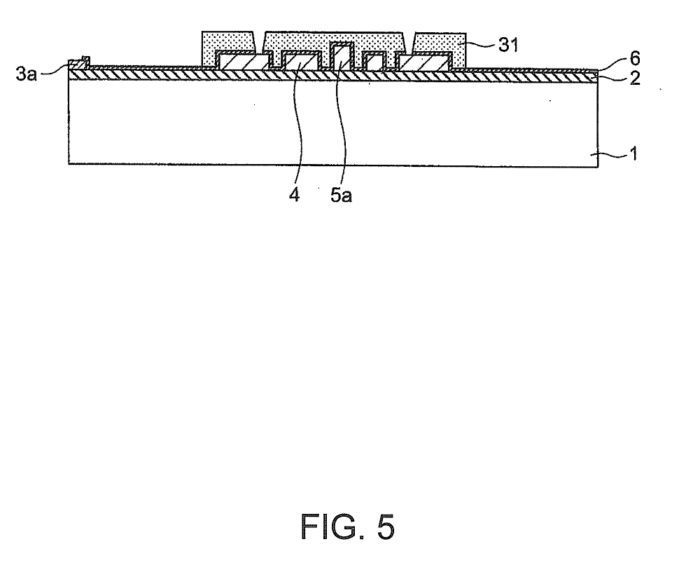

Then, as shown in FIG. 5, a first sacrificial layer 31 is formed by a coating method, for example, to have a thickness in the range of several hundred nm to several um on the insulating film 6. An unillustrated resist film is formed by using a well-known lithography process. Using this resist film as a mask, the first sacrificial layer 31 is patterned to have a desired shape by an RIE process, for example. After this resist film is removed, using a resist film again as a mask, the insulating film 6 on the wiring layer 4 is etched by using an RIE (Reactive Ion Etching) process, for example, to form openings. Thereby, the surface of the wiring layer 4 is exposed therefrom. The resist film is removed.

Here, a polyimide resin is used as the first sacrificial layer 31; instead, an organic film such as a BCB (Benzo-Cycro-Buten) resin, a fluorinated resin (parylen-N or the like), or a polyamide resin may be used.

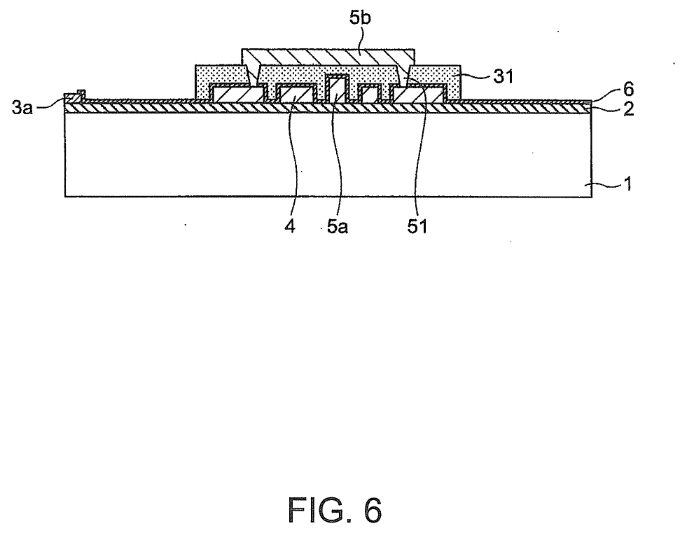

Subsequently, as shown in FIG. 6, a wiring layer is patterned to have a thickness in the range of several hundred nm to several um in the openings and on the first sacrificial layer 31. As a result, formed is the second electrode 5b having the anchor portions 51 connected to the wiring layer 4. The first electrode 5a and the second electrode 5b serve as the actuation portion of the MEMS element.

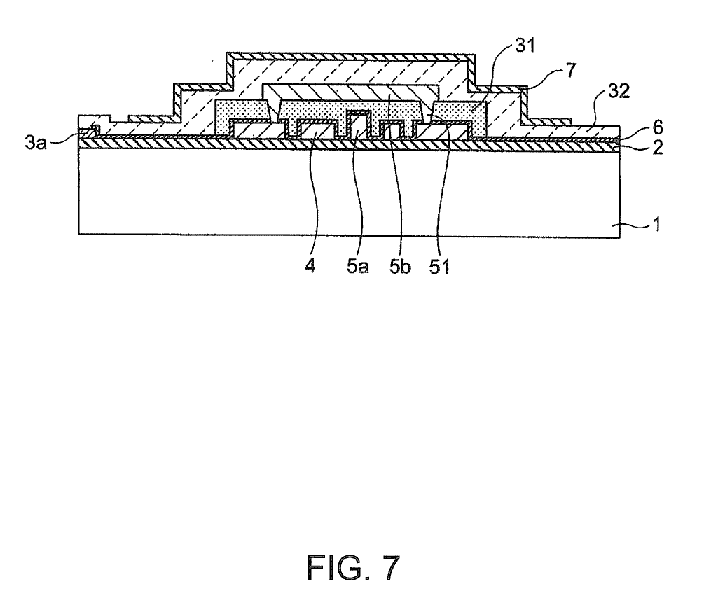

Thereafter, as shown in FIG. 7, a second sacrificial layer 32 and the insulating film 7 are successively formed on the insulating film 6, the first sacrificial layer 31, and the second electrode 5b. The second sacrificial layer 32 is formed by a coating method, for example, to have a thickness in the range of several hundred nm to several um. The insulating film 7 is formed by a CVD process, for example, to have a thickness in the range of several hundred nm to several um. After the second sacrificial layer 32 and the insulating film 7 are formed, an unillustrated resist film is formed by using a well-known lithography process. Using this resist film as a mask, the insulating film 7 is etched by using an RIE process, for example. The resist film is removed.

Here, a polyimide resin is used as the second sacrificial layer 32; instead, an organic film such as a BCE (Benzo-Cycro-Buten) resin, a fluorinated resin (parylen-N or the like), or a polyamide resin may be used.

Note that, in this embodiment, the second sacrificial layer 32 is provided to completely cover the periphery (an upper portion and a side surface) of the first sacrificial layer 31. If, as in Comparative Example shown in FIG. 8, for example, a second sacrificial layer 32a is formed only on an upper portion of a first sacrificial layer 31a, this causes: the plasma damage to a region where the first sacrificial layer 31a is exposed; reduction in the thickness of the first sacrificial layer 31a; and so forth. The reduction in the thickness of the sacrificial layer 31a leads to a problem that a desired cavity structure cannot be formed. Moreover, another problem occurs that the surface of the first sacrificial layer 31a is roughened due to the process damage in the step of forming an insulating film on a cavity region, thereby causing a MEMS element and the second sacrificial layer 32a to be peeled from the substrate 1 in the subsequent step.

Meanwhile, in this embodiment, to form the first to the third cavity regions as shown in FIGS. 1 to 3, the height of the second sacrificial layer 32 is varied. However, the way to achieve this purpose is not necessarily limited to this. For example, the second sacrificial layer 32 may be formed to have a constant height throughout, and the first to the third cavity regions thus may have the same heights. Alternatively, the second sacrificial layer 32 may be formed to have a constant height on a peripheral portion around the MEMS element region 200, and the second and the third cavity regions thus may have the same heights.

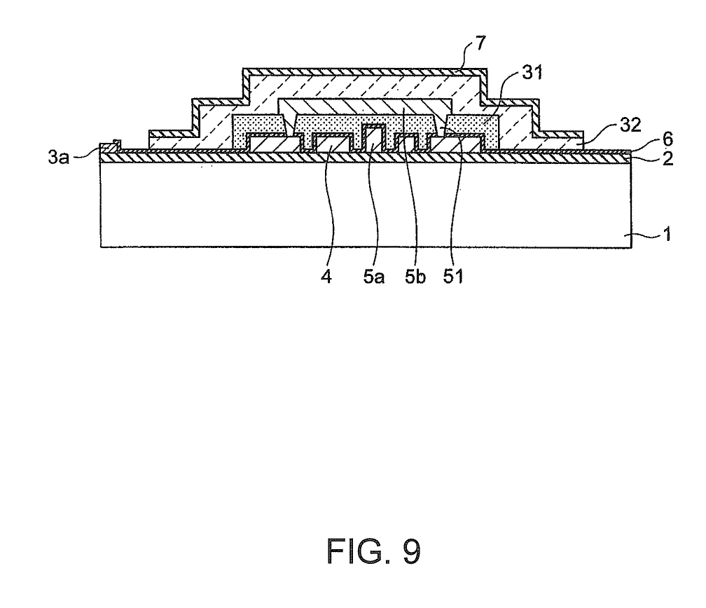

Then, as shown in FIG. 9, using the insulating film 7 as a mask, the second sacrificial layer 32 is etched by using an RIE process, for example. Here, although the RIE process is used to etch the second sacrificial layer 32, a wet etching process may be used instead.

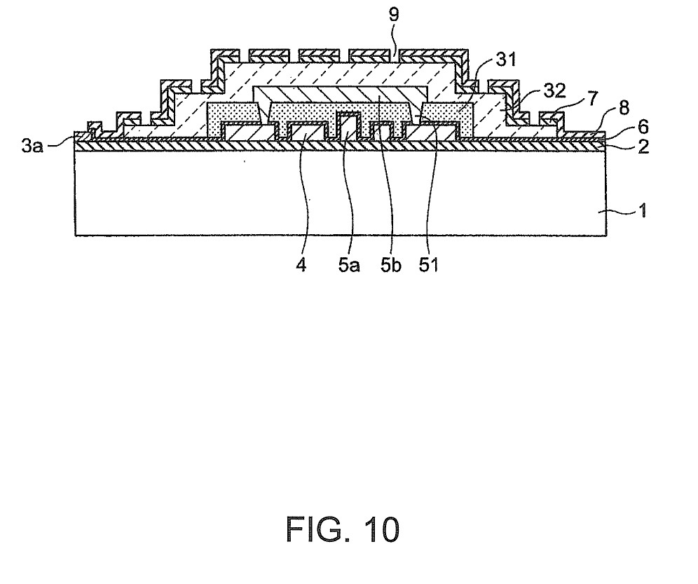

Subsequently, as shown in FIG. 10, the insulating film 8 is formed on terminal 3a, the insulating film 6 and the insulating film 7 by using a CVD process, for example. After the insulating film 8 is formed, an unillustrated resist film is formed by using a well-known lithography process. Using this resist film as a mask, the insulating film 8 and the insulating film 7 are successively etched by an RIE process, for example, to thereby form the openings 9 on the first cavity region 100, the second cavity region 101, and the third cavity region 102. The resist film is removed.

Here, the openings 9 are formed on the first cavity region 100, the second cavity region 101, and the third cavity region 102. However, the way to form the openings 9 is not necessarily limited to this. The positions and the number of the openings 9 may be altered as necessary.

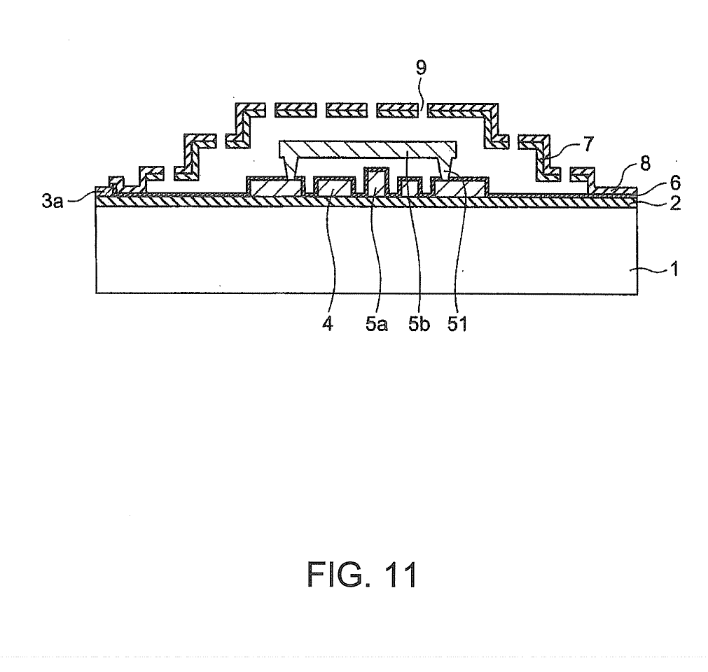

Thereafter, as shown in FIG. 11, the second sacrificial layer 32 and the first sacrificial layer 31 is removed by using an ashing process, for example. The second sacrificial layer 32 and the first sacrificial layer 31 thus turned into ash by the ashing process are discharged outside through the openings 9. As a result, the first cavity region 100, the second cavity region 101, and the third cavity region 102 are formed.

Here, in the ashing process, an oxygen (O₂) gas is used; instead, an ozone (O₃) gas may be used. When an ozone (O₃) gas is used, the plasma damage occurs less frequently than the case of an oxygen (O₂) gas. The plasma damage causes damage to the insulating films by charged particles.

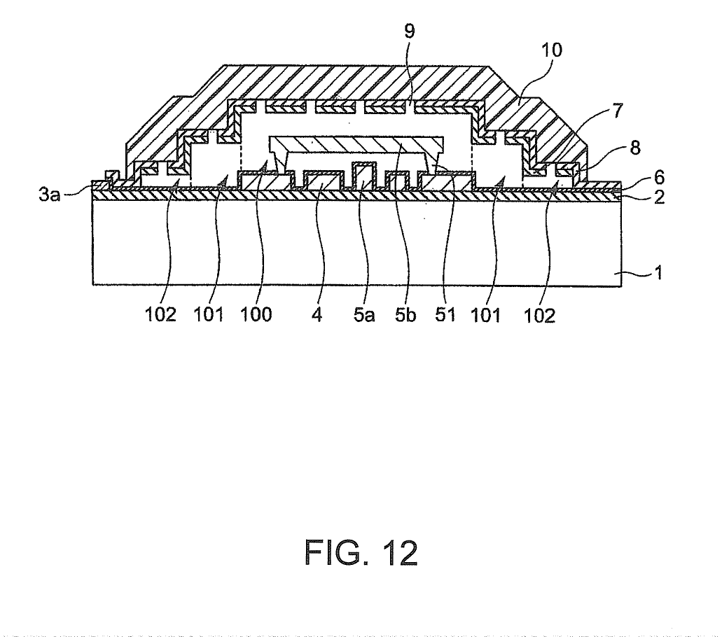

Then, as shown in FIG. 12, the organic film 10 is formed on the terminal 3a and the insulating film 8 by a coating method to seal the openings 9. In the formation of the organic film 10, it is important to set the viscosity of the organic film 10, the number of revolutions in the coating method, and the like under appropriate conditions as necessary so as not to let the organic film 10 enter the first cavity region 100, the second cavity region 101, and the third cavity region 102.

After the organic film 10 is formed by coating, the organic film 10 outside the MEMS device region is etched. The insulating film 11 is formed on the organic film 10 and the insulating film 8 by using a CVD process, for example. The insulating film 11 outside the MEMS device region is etched. Thus, the MEMS device 80 is completed. Note that the insulating film 11 is used as a measure against moisture for the MEMS device 80, for example.

As has been described, in the MEMS device and the method for manufacturing a MEMS device of this embodiment, the first cavity region 100 is provided in the MEMS element region 200. The second cavity region 101 having a lower height than the first cavity region 100 is provided on the surrounding portion outside the first cavity region 100. The third cavity region 102 having a lower height than the second cavity region 101 is provided on the surrounding portion outside the second cavity region 101. The insulating film 7 is provided on the first cavity region 100, the second cavity region 101, and the third cavity region 102. The insulating film 8 is provided on the insulating film 7 and the side surface of the third cavity region 102 to cover the first cavity region 100, the second cavity region 101, and the third cavity region 102. The openings 9 are provided in the laminated insulating films 7 and 8. The sealant including the organic film 10 and the insulating film 11 is provided to seal the openings 9. In the step of forming the cavity regions, the first sacrificial layer 31 is formed to cover the insulating film 6 on the wiring layer 4, and the second sacrificial layer 32 having a larger area than the first sacrificial layer 31 is provided to completely cover both of the first sacrificial layer 31 and the second electrode 5b. The first sacrificial layer 31 and the second sacrificial layer 32 are removed by the ashing process. The second sacrificial layer 32 protects the surface of the first sacrificial layer 31 until the cavity regions are formed.

Consequently, a cavity region having a stable form can be formed in the MEMS element region 200. Moreover, it becomes possible to prevent the surface roughness of the first sacrificial layer 31 due to the plasma damage in the process step, and prevent peeling of the MEMS element and the second sacrificial layer 32 from the substrate 1. Thus, improvements in the reliability and the yield of the MEMS device 80 are achieved.

Note that, in this embodiment, the organic film 10 and the insulating film 11 are used as the sealant; nevertheless, only an organic film may be used as the sealant for cases where a MEMS device has a relatively low moisture resistance requirement and where a measure against moisture is implementable when a MEMS device is mounted on a module.

### Second Embodiment

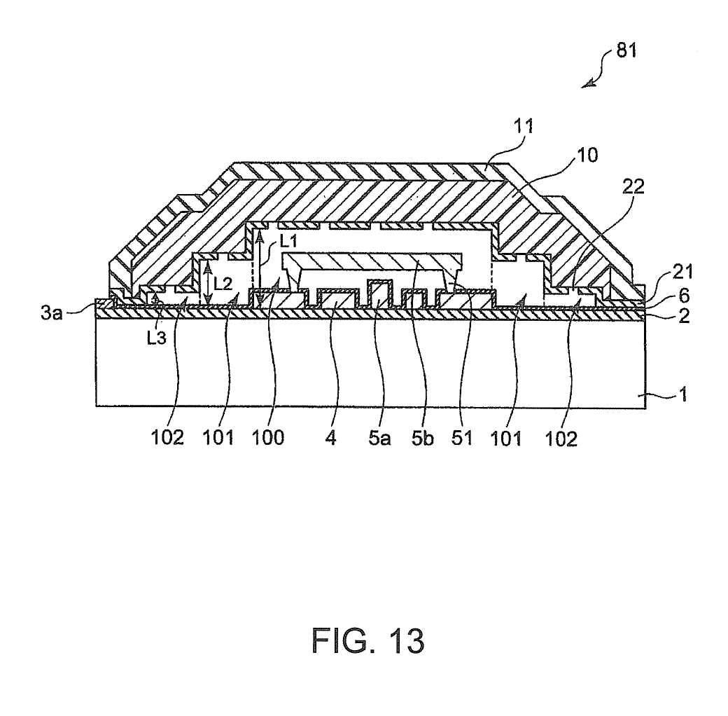

Next, a MEMS device and a method for manufacturing a MEMS device according to Embodiment 2 of the present invention will be described with reference to the drawings. FIG. 13 is a cross-sectional view showing the MEMS device. In this embodiment, the structure of insulating films covering a cavity region is simplified.

Hereinbelow, like reference numerals designate identical constituent parts to those in Embodiment 1, the description thereof will be omitted, and only different parts will be described.

As shown in FIG. 13, a MEMS device 81 is an RF-MEMS provided with an actuation portion in the MEMS element region 200. The RF-MEMS is employed to, for example, high-frequency components such as mobile devices, and specifically employed to a device such as a switch, a filter, or a varactor. In the MEMS device 81, the first cavity region 100 having the distance L1 between the substrate and the insulating film is provided on the MEMS element region 200. The second cavity region 101 having the distance L2 between the substrate and the insulating film is provided on the insulating film 6 on the surrounding portion outside the first cavity region 100. The third cavity region 103 having the distance L3 between the substrate and the insulating film is provided on the insulating film 6 on the surrounding portion outside the second cavity region 101.

An insulating film 21 is provided on the first cavity region 100, the second cavity region 101, and the third cavity region 102 as well as on the side surface of the third cavity region 102 to cover the first cavity region 100, the second cavity region 101, and the third cavity region 102. Openings 22 are provided in the insulating film 21 on the first cavity region 100, the second cavity region 101, and the third cavity region 102. The organic film 10 is provided on the insulating film 21 to seal the opening 22. The insulating film 11 is provided on the organic film 10 and the insulating film 22.

Here, a silicon nitride film (SiN film) is used as the insulating film 21; instead, a silicon oxide film (SiO₂), a SiON film, a SiOCH film, or the like may be used.

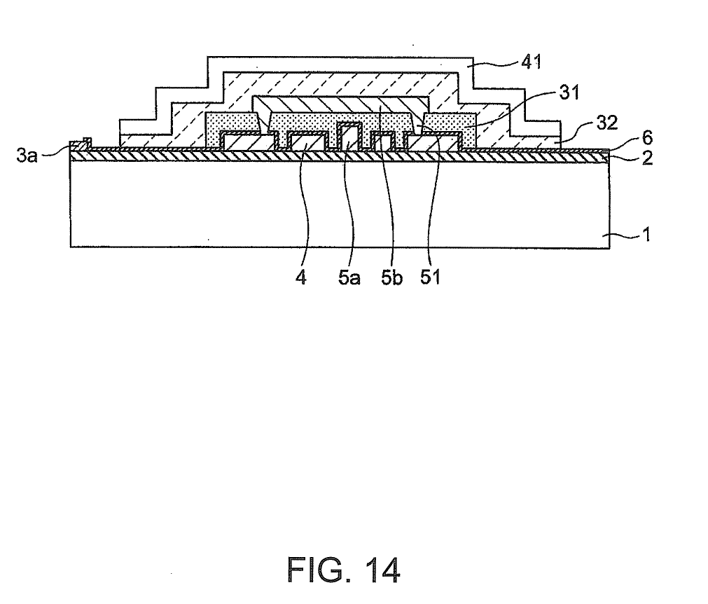

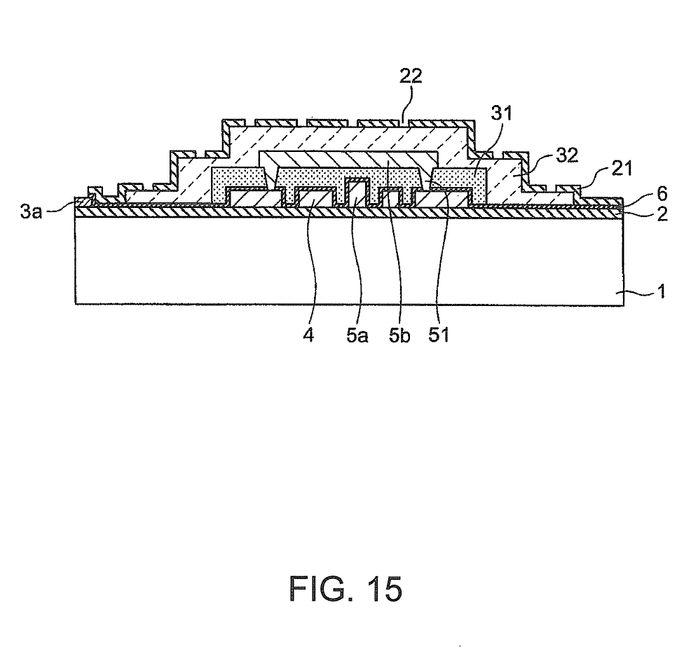

Next, a method for manufacturing a MEMS device will be described with reference to FIGS. 14 and 15. FIGS. 14 and 15 are cross-sectional views illustrating manufacturing steps for the MEMS device. In this embodiment, the steps until the step for the second sacrificial layer 32 are the same as those in Embodiment 1.

As shown in FIG. 14, a resist film 41 is formed on the second sacrificial layer 32 by using a well-known lithography process. Using the resist film 41 as a mask, the second sacrificial layer 32 is etched by using an RIE process, for example. Here, although the second sacrificial layer 32 is etched by using the RIE process, a wet etching process may be used instead. The resist film 41 is removed.

Subsequently, as shown in FIG. 15, the insulating film 21 is formed on the terminal 3a, the insulating film 6 and the second sacrificial layer 32 by using a CVD process, for example. After the insulating film 21 is formed, an unillustrated resist film is formed by using a well-known lithography process. Using this resist film as a mask, the insulating film 21 is etched by an RIE process, for example, to thereby form the openings 22 on the first cavity region 100, the second cavity region 101, and the third cavity region 102. The resist film is removed. The subsequent steps are the same as those in Embodiment 1, and accordingly the description will be omitted.

As has been described, in the MEMS device and the method for manufacturing a MEMS device of this embodiment, the first cavity region 100 is provided on the MEMS element region 200. The second cavity region 101 having a lower height than the first cavity region 100 is provided on the surrounding portion outside the first cavity region 100. The third cavity region 102 having a lower height than the second cavity region 101 is provided on the surrounding portion outside the second cavity region 101. The insulating film 21 is provided on the periphery of the first cavity region 100, the second cavity region 101, and the third cavity region 102. The openings 22 are provided in the insulating film 21. The sealant including the organic film 10 and the insulating film 11 is provided to seal the openings 22. In the step of forming the cavity regions, the first sacrificial layer 31 is formed to cover the insulating film 6 on the wiring layer 4, and the second sacrificial layer 32 having a larger area than the first sacrificial layer 31 is provided to completely cover both of the first sacrificial layer 31 and the second electrode 5b. The first sacrificial layer 31 and the second sacrificial layer 32 are removed by the ashing process. The second sacrificial layer 32 protects the surface of the first sacrificial layer 31 until the cavity regions are formed.

Consequently, in addition to the effects of Embodiment 1, shortening of the process is achieved. Thus, reduction in the manufacturing cost for the MEMS device 80 can be achieved.

### Third Embodiment

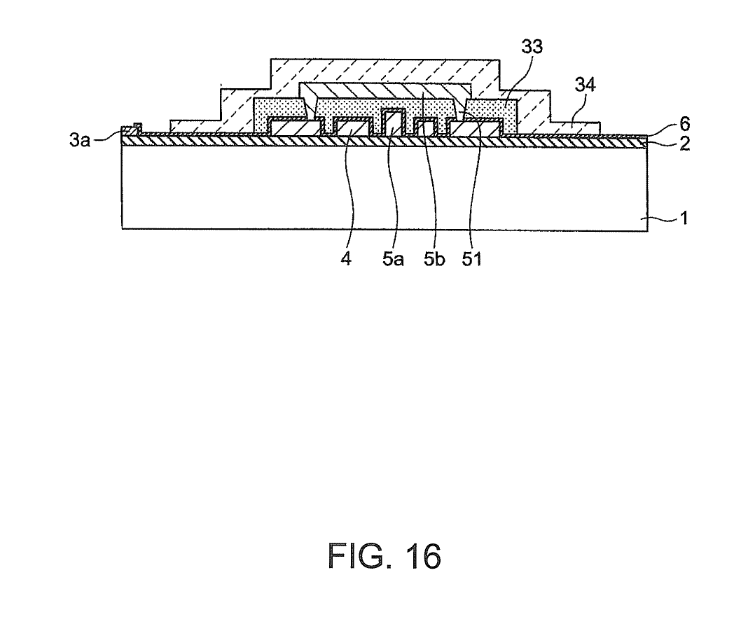

Next, a method for manufacturing a MEMS device according to Embodiment 3 of the present invention will be described with reference to the drawing. FIG. 16 is a cross-sectional view illustrating a manufacturing step for a MEMS device. In this embodiment, the manufacturing step for a MEMS device is shortened.

Hereinbelow, like reference numerals designate identical constituent parts to those in Embodiment 1, the description thereof will be omitted, and only different parts will be described.

As shown in FIG. 16, a first sacrificial layer 33 is formed on the insulating film 6 by a coating method, for example. The first sacrificial layer 33 is photosensitive polyimide resin, for example. By using a well-known lithography process, the first sacrificial layer 33 is irradiated with light to modify and etch away the irradiated portion of the first sacrificial layer 33. After the first sacrificial layer 33 is formed, using a resist film as a mask, the insulating film 6 on the wiring layer 4 is etched by using an RIE (Reactive Ion Etching) process, for example, to form openings. Thereby, the surface of the wiring layer 4 is exposed. The resist film is removed. Incidentally, the openings may be formed using the first sacrificial layer 33 as the mask in place of the resist film.

Then, the wiring layer is patterned in the openings and on the first sacrificial layer 33. As a result, formed is the second electrode 5b having the anchor portions 51 connected to the wiring layer 4. The first electrode 5a and the second electrode 5b serve as the actuation portion of the MEMS element.

Subsequently, a second sacrificial layer 34 is formed on the insulating film 6, the first sacrificial layer 33, and the second electrode 5b by a coating method, for example. The second sacrificial layer 34 is photosensitive polyimide resin, for example. By using a well-known lithography process, the second sacrificial layer 34 is irradiated with light to modify and etch away the irradiated portion of the second sacrificial layer 34. The subsequent steps are the same as those in Embodiment 1, and accordingly the description will be omitted. As has been described, in the method for manufacturing a MEMS device of this embodiment, the first sacrificial layer 33 is formed to cover the insulating film 6 on the wiring layer 4, and the photosensitive second sacrificial layer 34 having a larger area than the first sacrificial layer 33 is provided to completely cover both of the first sacrificial layer 33 and the second electrode 5b. The first sacrificial layer 33 and the second sacrificial layer 34 are removed by the ashing process. The second sacrificial layer 34 protects the surface of the first sacrificial layer 33 until the cavity regions are formed.

Consequently, in addition to the effects of Embodiment 1, shortening of the process is achieved. Thus, reduction in the manufacturing cost for the MEMS device 80 can be achieved.

The present invention is not limited to the above-described embodiments, and various modifications are possible within the scope not departing from the gist of the invention.

In the embodiments, the invention is employed to an RF-MEMS, but can also be employed to an optical MEMS, a sensor MEMS, a bio-MEMS, and the like. Examples of the optical MEMS include an optical communication switch, and the like. Examples of the sensor MEMS include an accelerometric sensor, an infrared sensor, five-senses sensors, and the like. Examples of the bio-MEMS include a medical biosensor, and the like.

Embodiments of the invention have been described with reference to the examples. However, the invention is not limited thereto.

Other embodiments of the present invention will be apparent to those skilled in the art from consideration of the specification and practice of the invention disclosed herein. It is intended that the specification and example embodiments be considered as exemplary only, with a true scope and spirit of the invention being indicated by the following.

What is claimed is:

1. A method for manufacturing a MEMS device characterized by comprising the steps of:
forming a first wiring layer on a substrate;
forming a first insulating film on the first wiring layer and the substrate;
forming a first sacrificial layer on the first insulating film to cover the first wiring layer, and forming a first opening by etching the first sacrificial layer and the first insulating film to expose a surface of the first wiring layer;
forming a MEMS element by providing a second wiring layer in the opening and on the first sacrificial layer, the second wiring layer using as an anchor portion a portion buried in the opening;
forming a second sacrificial layer on the first insulating film, the second wiring layer, and the first sacrificial layer;
forming a second insulating film on the second sacrificial layer, the second insulating film having a larger area than a region where the second wiring layer and the first sacrificial layer are disposed;
etching the second sacrificial layer by using the second insulating film as a mask;
forming a third insulating film on the second insulating film and the first insulating film;
forming a second opening by etching the second and the third insulating films on the second sacrificial layer;
removing the first and the second sacrificial layers through the second opening; and
forming a sealant on the third insulating film to seal the second opening and to retain a cavity region provided in a region where the MEMS element is formed.

2. The method for manufacturing a MEMS device according to claim 1, wherein, in the step of forming the second sacrificial layer, an upper portion and a side surface of the first sacrificial layer is covered.

3. The method for manufacturing a MEMS device according to claim 1, wherein the step of forming the second insulating film is performed in a state where the second sacrificial layer covers an upper portion and a side surface of the first sacrificial layer.

4. The method for manufacturing a MEMS device according to claim 1, wherein the step of forming the third insulating film is performed in a state where the second sacrificial layer covers an upper portion and a side surface of the first sacrificial layer.

5. The method for manufacturing a MEMS device according to claim 1, characterized in that the second sacrificial layer is patterned by any one of a RIE process and a wet etching process using a resist film as a mask.

6. The method for manufacturing a MEMS device according to claim 1, characterized in that the sealant includes an organic film and an insulating film on the organic film.

7. A MEMS device characterized by comprising:
a MEMS element;
a first cavity region provided on the MEMS element;
a second cavity region provided on a surrounding portion outside the MEMS element, the second cavity region having a lower height than the first cavity region;
a third cavity region provided on a surrounding portion outside the second cavity region, the third cavity region having a lower height than the second cavity region;
an insulating film provided to cover upper portions and side surfaces of the first to the third cavity regions;
an opening provided in the insulating film on the first to the third cavity regions; and
a sealant provided on the insulating film to seal the opening and to retain the first to the third cavity regions.

8. The MEMS device according to claim 7, wherein
the insulating film includes:
a first insulating film provided on the first to the third cavity regions; and
a second insulating film provided on the first insulating film and the side surface of the third cavity region to cover a periphery of the first to the third cavity regions.

9. The MEMS device according to claim 7, wherein the sealant includes a polyimide film and an insulating film on the polyimide film.

10. The MEMS device according to claim 7, wherein the third cavity region has a larger plan area than the second cavity region.

11. The MEMS device according to claim 7, wherein the second cavity region has a larger plan area than the first cavity region.

12. The MEMS device according to claim 7, wherein the third cavity region has a larger plan area than the second cavity region, and the second cavity region has a larger plan area than the first cavity region.

13. The MEMS device according to claim 7, wherein the MEMS element is formed on a MEMS element region provided with: a first wiring layer provided on a substrate; and a second wiring layer disposed above and apart from the first wiring layer, the second wiring layer having an anchor portion connected to the first wiring layer.
